(19) United States
(12) Patent Application Publication
(10) Pub. No.: US 2012/0187301 A1
(43) Pub. Date: Jul. 26, 2012

(54) Method of Using Radon Detection for Locating Thermals

(76) Inventor: Ralph J. Markson, Weston, MA (US)

(21) Appl. No.: 13/357,943

(22) Filed: Jan. 25, 2012

Related U.S. Application Data
(60) Provisional application No. 61/436,381, filed on Jan. 26, 2011.

(51) Int. Cl. G01T 1/02; G01R 27/00; G01T 1/20

(52) U.S. Cl. 250/362; 250/395; 324/691

(57) ABSTRACT

A method of locating a thermal updraft. In one embodiment, the method includes the steps of flying an aircraft in a flight path; making ionization measurements at a plurality of locations along the aircraft flight path using an ionization measuring device to measure ionization rate; determining in response to the ionization measurements areas of increased ionization rate; and denoting areas of increased ionization rate as areas of thermal updraft. In another embodiment, the method includes the steps of measuring ionizing radiation at each location along the aircraft flight path; and if ionizing radiation levels are above a predetermined value, determining that the location is within a thermal updraft and if the ionizing radiation levels are below a predetermined value, determining that the location is outside of a thermal updraft.

### RELATED APPLICATIONS

This application claims priority to U.S. Provisional Patent Application No. 61/436,381, filed Jan. 26, 2011, and incorporated herein in its entirety by reference.

### FIELD OF THE INVENTION

The invention relates to the detection of atmospheric thermal updrafts and more specifically to the detection of thermal updrafts using measurements of ionizing radiation.

### BACKGROUND OF THE INVENTION

Sailplanes or gliders are unpowered aircraft that utilize the wind and atmospheric currents to stay aloft. Generally, the sailplane is brought to altitude by being towed by a powered aircraft. At that altitude, the tow cable to the powered aircraft is released and the pilot of the sailplane seeks upwardly moving air to gain altitude.

Finding such updrafts or thermals requires pilot experience. Sailplane pilots look at the geography and exercise judgment as to where an updraft may be. The pilot then searches for an updraft to help him or her remain aloft for an extended period of time.

What is needed is a way for pilots to determine the presence of thermal updrafts. The present invention addresses this need.

### SUMMARY OF THE INVENTION

In one aspect, the invention relates to a method of locating a thermal updraft. In one embodiment, the method includes the steps of flying an aircraft in a flight path; making ionization measurements at a plurality of locations along the aircraft flight path using an ionization measuring device to measure the rate of ionization and the change in the rate of ionization; determining, in response to the change in ionization rate measurements, areas of increased ionization rate; and denoting areas of increased ionization rate as areas of thermal updraft. In another embodiment, the method further includes the steps of measuring at least one of alpha, beta and gamma radiation intensity level at each location along the aircraft flight path; and if ionization rate at a respective location is above a predetermined value and if the alpha, beta and gamma radiation intensity levels are above predetermined levels, determining that the location is within a thermal updraft and if ionization rate at the respective location is above a predetermined value and if alpha and beta radiation levels are below a predetermined value determining that the location is outside of a thermal updraft. In yet another embodiment, the ionization measurement is a conductivity measurement. In still yet another embodiment, the ionization measuring device is selected from the group of measuring devices consisting of a Geiger counter, an ion chamber and a scintillation counter. In one embodiment, the method further includes the step of mapping contours of substantially equal ionization rate. In another embodiment, the method further comprises the step plotting the contours on a geographic map. In yet another embodiment, the areas of increased ionization are denoted in a time graph. In still yet another embodiment, the areas of increased ionization are denoted by an increase in repetition rate of audible sounds. In one embodiment, increased ionization is defined as above background ionization.

In another aspect, the invention relates to another method of locating a thermal updraft. In one embodiment, the method includes the steps of flying an aircraft in a flight path; detecting radon concentrations at a plurality of locations along the aircraft flight path using an ionization measuring device to measure changes in ionization; determining, in response to the changes in ionization measurements, areas of increased radon concentration; and denoting areas of increased radon concentration as areas of thermal updraft. In another embodiment, the method further includes the steps of measuring at least one of alpha, beta and gamma radiation at each location along the aircraft flight path; and if the changes in ionization are above a predetermined level and if alpha and beta radiation levels are above a predetermined value, determining that the location is within a thermal updraft, and if the changes in ionization are above a predetermined level and if alpha and beta radiation levels are below a predetermined value, determining that the location is outside of a thermal updraft.

In yet another aspect, the invention relates to a device for locating a thermal updraft. In one embodiment, the device includes a conductivity sensor; an electrometer in electrical communication with the conductivity sensor; and a display for showing values of conductivity as a function of time and location. In another embodiment, the conductivity sensor includes a cylindrical first electrode; and a second electrode positioned within the first electrode; and a preamplifier in electrical communication with the second electrode. In yet another embodiment, the electrometer includes an isolation amplifier having an output terminal; and an operational amplifier having a first input terminal in electrical communication with the output terminal of the isolation amplifier; an operational amplifier output terminal in electrical communication with the first input terminal of the operational amplifier; and an electrometer output terminal in electrical communication with the operational amplifier output terminal.

In another embodiment, the conductivity sensor includes a cylindrical first grounded shield; a cylindrical first electrode within the first grounded shield; and a second electrode positioned within the first electrode; and a preamplifier in electrical communication with the second electrode. In yet another embodiment, the electrometer includes an operational amplifier having a first input terminal in electrical communication with the output terminal preamplifier; an operational amplifier output terminal in electrical communication with the first input terminal of the operational amplifier; and an electrometer output terminal in electrical communication with the operational amplifier output terminal.

### BRIEF DESCRIPTION OF THE DRAWINGS

The objects and features of the invention can be better understood with reference to the drawings described below, and the claims. The drawings are not necessarily to scale, emphasis instead generally being placed upon illustrating the principles of the invention. In the drawings, like numerals are used to indicate like parts throughout the various views. The drawings associated with the disclosure are addressed on an individual basis within the disclosure as they are introduced.

FIG. 1 is a circuit diagram of an embodiment of a sensor for measuring air conductivity for the purpose of locating a thermal updraft;

FIG. 2 is a circuit diagram of an embodiment of a measurement circuit for use with the sensor in FIG. 1;

FIG. 3 is a circuit diagram of another embodiment of a sensor for measuring air conductivity for the purpose of locating an thermal updraft; and

FIG. 4 is a circuit diagram of an embodiment of a measurement circuit for use with the sensor in FIG. 3.

### DESCRIPTION OF AN EMBODIMENT OF THE INVENTION

During sailplane flights, a conductivity sensing system on the glider will indicate that there are rapid increases in conductivity near regions of lift. Normally, conductivity is fairly constant at constant altitude above the turbulent mixed layer in the lower atmosphere, because ion production is controlled by the relatively constant flux of cosmic radiation. Cosmic ray radiation, which is very energetic, and secondary cosmic radiation, ionizes the atmosphere at a relatively constant rate at a given altitude. An increase in conductivity above this background implies an increase in ionizing rate. The rapid increases in conductivity, which can be on the order of 2 to 10 times the conductivity that results from the normal cosmic radiation baseline value, is hypothesized to be due to the presence of radon; the decay of which ionizes the air. Upon decaying, radon emits alpha particles, beta particles, and gamma ionizing radiation. Alpha particles have a relatively short range on the order of centimeters. Beta particles have longer range (on the order of meters to tens of meters) and the gamma radiation has an even longer range depending on energy (on the order of meters to hundreds of meters). This gamma radiation is radiation from the radon source and is not gamma radiation from cosmic radiation.

Radon is formed from the decay of uranium byproducts within the earth. The radon so formed is a gas that escapes through the ground and into the air, forming a layer of ionized air close to the Earth's surface. Thermal updrafts are rising bubbles and columns of air caused by heating of the ground. Such thermals entrain the air containing radon close to the ground, thereby carrying radon aloft. Radon has a half-life of 3.8 days so it will rise with the thermal to the top of the atmospheric exchange layer, which is typically the level of the temperature inversion, a few thousand feet above the ground. Thus, the radon will be within the thermal air column as well as in volumes accumulated at and near the inversion layer. These ionized air volumes remain in the atmosphere and drift with the wind.

A measured increase in ionization rate, as shown by an increase in conductivity above background caused by radon decay, means that the glider making the measurement is either within the air volume containing radon or close to it; probably within a few hundred meters. The background level is determined by observing that the ionization rate measured is relatively constant, e.g., with a variation of less than +/−5% at constant altitude. Larger variations in ionization rate are due to the presence of an additional ionizing source. Ionization itself and change in rate of ionization can be observed through measurements of conductivity, Geiger counter pulse rate, ion chamber electrical output or scintillation counter rate. The sailplane need not be in the radon containing air volume to measure increased conductivity or ionization rate because gamma radiation from the radon decay in the rising column can cause an increase in conductivity in regions outside the volume containing the radon gas. Thus, conductivity or other ionization rate measurements provide a method for determining that the glider is in or near a thermal updraft where there is lift useful for keeping a glider aloft.

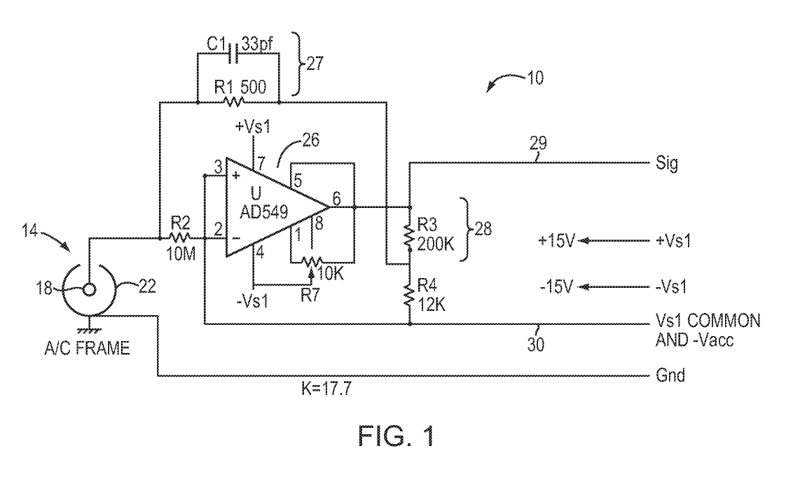

Referring to FIG. 1, in one embodiment, ionization rate, as shown by changes in conductivity, is measured by a Gerdien capacitor sensor 10. This instrument requires an airflow through a capacitor 14 (in one embodiment, of cylindrical form) in which a transverse electric field is maintained by a DC voltage between a center electrode 18 and the outer conductive cylinder 22. This electric field causes ions in the air flowing through the capacitor 14 to drift to one of the electrodes of the capacitor (either toward the center electrode or the outer cylinder depending on polarity), and the very small picoamp current is measured.

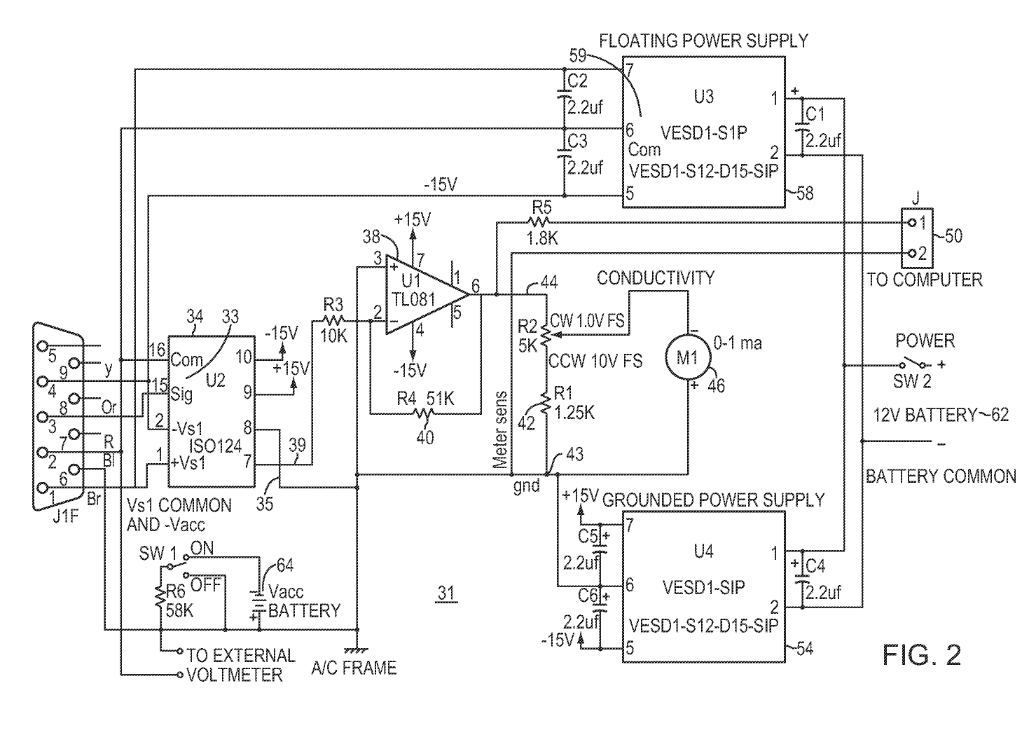

In the embodiment shown, the outer cylinder 22 is grounded and the signal from the center electrode 18 is the input signal to both input terminals of a pre-amplifier 26 and one terminal of an RC circuit 27. In one embodiment, the pre-amplifier 26 is an AD549 operational amplifier (Analog Devices, Norwood, Mass.). The other terminal of the RC circuit 27 is connected to the midpoint of a voltage divider 28. The two input terminals of the pre-amplifier 26 are also connected to a thirty volt source through line 30 as is the first terminal of the voltage divider 28. The output signal of the pre-amplifier 26 is the input signal to the second terminal of the voltage divider 28 and the input 29 to a high impedance electrometer 31 (FIG. 2).

Referring to FIG. 2, the output signal line 29 (FIG. 1) from the pre-amplifier 26 is connected to the input signal terminal 33 of a high precision isolation amplifier 34. In one embodiment, the high precision isolation amplifier is an ISO124 (Burr Brown, Tucson Ariz.). The ground 35 of the high precision isolation amplifier 34 is connected to system ground and one input terminal of an operational amplifier 38. In one embodiment, the operational amplifier 38 is a TL081 (STMicroelectronics, Geneva, Switzerland). The output signal terminal 39 of the precision isolation amplifier 34 is connected to a second input terminal of the operational amplifier 38. The output signal of the operational amplifier 38 is fed back through a resistor 40 to the second input terminal of the operational amplifier 38 and one terminal of a voltage divider 42. The other terminal 43 of the voltage divider is connected to ground. One terminal of a milliamp meter 46 is connected to a variable resistor 44 of the voltage divider 42. The other terminal of the meter 46 is connected to ground. By adjusting the contact of the first terminal of the milliamp meter 46 in the voltage divider 42, the sensitivity of the milliamp meter 46 may be adjusted. In addition, the output of the operational amplifier 38 and the ground are provided to a cockpit computer (not shown) through a connector 50

Power is provided to the circuit 30 through a grounded power supply DC-to-DC converter 54 and a floating power supply DC-to-DC converter 58, both connected to a power source 62 for the aircraft. The power supply converter 58 provides a floating voltage and is connected such that the center electrode used to create the accelerating electric field is kept at a potential above aircraft ground. To accomplish this potential differential, a second battery 64 provides a negative voltage of about thirty volts to both the center electrode 18 and the pre-amplifier 26 input terminals (FIG. 1) of the sensor and to the common terminal 59 of the floating voltage converter 58. The positive terminal of the battery 64 is connected to the aircraft frame and the outer cylinder 22 of the sensor.

In the embodiment shown, the DC-to-DC converter 54 provides power to the operational amplifier 38 while the floating DC-to-DC converter provides power to the isolation amplifier 34 and the sensor amplifier 26. In one embodiment, the DC to DC converters 54, 58 are VESD1 DC to DC converters (V-Infinity, Tualatin, Oreg.). In this way, the rate of ion production caused by ionizing radiation can be measured and converted to a voltage which is displayable on a computer connected to connector 50 or by the milliamp meter 46.

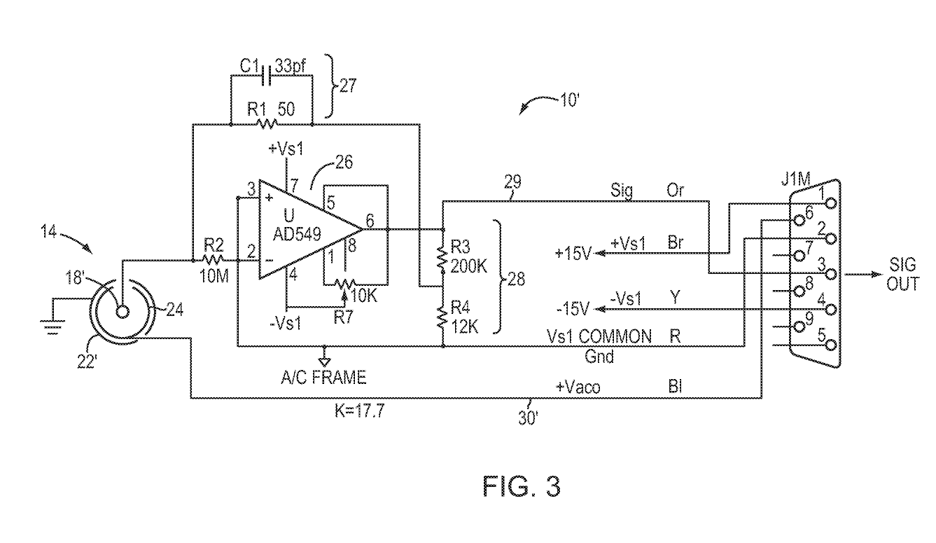

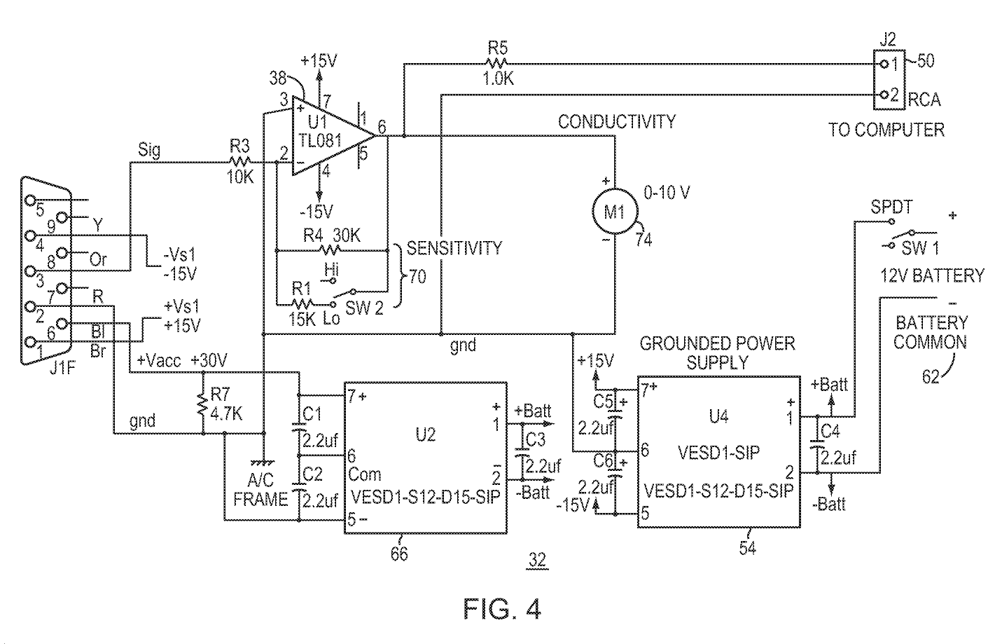

Referring to FIG. 3, in another embodiment the conductivity sensor 10′ is depicted in which the center electrode 18′ is surrounded by two concentric cylindrical electrodes 22′ and 24. As with the previous embodiment the outer cylindrical electrode 22′ is connected to ground and acts like a shield. The inner cylindrical electrode 24 however is connected to the positive terminal of a DC-to-DC converter 66 (FIG. 4) as described below. This inner cylindrical electrode 24 is thereby maintained at thirty volts relative to the center electrode 18′. The central electrode 18′ is connected to one input terminal of pre-amplifier 26 and one terminal of RC circuit 27. The other terminal of the RC circuit 27 is connected to the mid-point of a voltage divider 28. The second terminal of the voltage divider 28 is connected to ground and to the second input terminal of the pre-amplifier 26. The output signal terminal of the pre-amplifier 26 is connected to the input terminal of the voltage divider 28 and to the output line 29 to a high impedance electrometer 32 (FIG. 4).

Referring to FIG. 4 the electrometer circuit for use with conductivity sensor 10′ includes an operational amplifier 38 which has one input terminal connected to the output terminal 29 preamplifier 26 (FIG. 3). The second input terminal of operational amplifier 38 is connected to ground. The output terminal of operational amplifier 38 is connected through a resistor network 70 to the same input terminal of the operational amplifier 38 as is the output line 29 of pre-amplifier 26. The output terminal of operational amplifier 38 is also connected to one terminal of a 0-10V meter 74. The other terminal of the meter 74 is connected to ground. The output terminal of the operational amplifier 38 also provides the signals to a cockpit computer (not shown) through connector 50.

Power for the active components is delivered by the aircraft power battery 62 through a DC-to-DC converter 54. This converter provides ±15V power to the operational amplifier 38 and pre-amplifier 26 (FIG. 3). Power to bias the inner cylindrical electrode 34 is provided by a second DC-to-DC converter 66 also connected to the aircraft battery 62. Like the previous embodiment, both of these converters are VESD1 converters.

Although the use of the conductivity sensor (FIGS. 1-4) is described herein, there are other ways of measuring ionizing radiation, including an ion chamber, a Geiger counter (which measures alpha, beta and gamma radiation), and a scintillation counter (generally sodium iodide crystal with photoluminescence to measure gamma radiation). Because the conductivity sensor measures ionization caused by all three kinds of ionizing radiation, it is desirable to know if the radiation is from gamma radiation alone.

This differentiation can be made by including a Geiger counter with the conductivity sensor. A Geiger tube with a mica window measures alpha, beta and gamma radiation. By putting a thin metal sleeve around the Geiger tube, the alpha and beta radiation will be screened out and only the gamma radiation sensed. Also, by using a Geiger tube without a mica window, only the beta and gamma radiation will be sensed. Thus, through the combination of a conductivity sensor with one or more different types of Geiger tube sensors, it is possible to identify the kind of ionizing radiation being detected. This is desirable in determining if the glider is within a radon volume or if the radiation increase is coming from a nearby but different part of the atmosphere. Detecting alpha and beta radiation means the glider is within the radon cloud, while detecting solely gamma rays means the glider is near but not within an ionization volume.

The output of any of the measuring techniques is a scalar number that varies in time and space as the glider flies along. By observing the effect of movement on the rate of ionization using an analog or digital meter or as recorded by a computer or strip chart recorder, the pilot can determine where the thermal currents are in fact occurring.

Further, use of the computer allows the ionization and ionization rate to be displayed graphically in the cockpit, superimposed on a map to make the system operationally useful for glider pilots. In one embodiment, the method for using the data is to create a map with contours of radon concentration as determined from ionization rate similar to radar maps of, for example, rainfall intensity, where the color coding of the contours indicates precipitation rate. Radar rainfall maps generally go from green (light) to yellow (moderate) to red (heavy) to magenta (extreme) colors to indicate rainfall rate. This can be done relatively easily with radar because the radar beam is constantly rotating; sweeping out sectors of the sky rapidly and determining the distance to an echo. For the radon measurements the operation is more involved. Each conductivity or ionization measurement is only one measurement at one location at a point in time. Therefore, it is necessary to store that information as a function of the 3-dimensional position (latitude, longitude and altitude) of the aircraft in order to construct a contour map of the conductivity rate or ionization rate values.

Because radon has a half-life of 3.8 days it will persist in the atmosphere for minutes and hours before it eventually dissipates due to eddy diffusion. If the glider flies a pattern, which in one embodiment is a grid consisting of many small areas, the system will take readings throughout the grid. The computer can then average the values within each area (e.g. delineating two-dimensional space in a grid array) and calculate isopleths or contours of constant value for areas of different ionization rate. Many measurements within that grid box are averaged into one number representative of the average value in that box. Thus, equal value contour lines can be plotted for the overall grid array similar to elevation contour lines on a topographic map. When contour lines are closely spaced, this indicates regions where radon is coming to that part of the atmosphere and updraft locations.

To map out an area will take some time, but because the rate of dissipation is generally on the order of many minutes, the pattern is stable enough so that it may be used by the pilot to find the areas of maximum radon and hence the location of greatest updraft. In one embodiment, the map shows the spatial differences between a previous map and the current map, which is an indicator of developing or decreasing convective activity as a function of geographic position.

In one embodiment, the contours are shown on a graphic map presentation such as is currently readily available from a variety of GPS navigation systems; many of which are designed specifically for use on sailplanes. These systems show aircraft position, latitude, longitude, and altitude, and can also have ground contours as well as a history of the aircraft flight path. In various embodiments, contours can be defined by color, by gray-scale differences between areas, or by other non-color methods such as cross-hatching. In a simpler format, in one embodiment, the screen displays a linear time history such as would occur on a strip chart recorder so the pilot will see when the maximum signal was observed. For example, if the maximum value of ionization rate were one minute ago, the pilot could then reverse direction and return to the position of maximum ionization rate. Other variations are possible, such as flying in a circle to determine at which location on the circle, either on the GPS map or on the linear presentation, the maximum conductivity measurement is found. A variation on a linear presentation is a bar-graph time history chart.

In one embodiment, the output count rate and spatial and temporal variations of the Geiger counter measurement are recorded in the same fashion as the output of a conductivity tube. In the simplest form, in one embodiment, the output is audible beeps or deflection of a needle as on a Geiger counter display. In other words, a pilot may see the conductivity output indicate he or she is in a region of enhanced ionization, and if the Geiger counter also indicates a higher rate, the pilot knows the aircraft is within the radon cloud. If the Geiger counter output does not increase, the pilot knows the aircraft is near, but not in the ionizing source region and the pilot should execute a search to find the source region.

Sailplane pilots use changes in pulse repetition frequency or rate and pitch of the pulse signals to get an audible indication of lift from the rate-of-climb variometer instrument without having to look at a needle. The same approach can be used to determine the intensity of ionizing radiation rate and its change as the glider changes position. Considering the audible beeps one hears with a Geiger counter in which the beep repetition frequency indicates radiation intensity, one knows they are approaching or going away from a radiation source by an increase or decrease in repetition frequency. Similarly, when the beep frequency increases or decreases in a glider, the pilot would know he is approaching or going away from the thermal updraft source. In addition, the frequency of the beeps can change as is done with variometers; a higher pitch beep means approaching a thermal source while a lower pitch beep means flying away from a thermal source.

Whether the presentation is a graphic map or linear time history, it is important to clear the old display and start a new one when flying to a new area with new regions of radon. However, it is desirable to keep the old data in memory so the glider can fly back to previously observed radon-rich regions.

Because volumes with radon will move with the wind, it is useful to depict the wind field on the graphic display. This information is available from air data systems and from GPS systems. The pilot generally wants to fly to the geographic location where the radon cloud originated, which can be determined by flying upwind from regions of enhanced ionization.

The use of headings and sections in the application is not meant to limit the invention; each section can apply to any aspect, embodiment, or feature of the invention.

Throughout the application, where compositions are described as having, including, or comprising specific components, or where processes are described as having, including or comprising specific process steps, it is contemplated that compositions of the present teachings also consist essentially of, or consist of, the recited components, and that the processes of the present teachings also consist essentially of, or consist of, the recited process steps.

In the application, where an element or component is said to be included in and/or selected from a list of recited elements or components, it should be understood that the element or component can be any one of the recited elements or components and can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein.

The use of the terms “include,” “includes,” “including,” “have,” “has,” or “having” should be generally understood as open-ended and non-limiting unless specifically stated otherwise.

The use of the singular herein includes the plural (and vice versa) unless specifically stated otherwise. Moreover, the singular forms “a,” “an,” and “the” include plural forms unless the context clearly dictates otherwise. In addition, where the use of the term “about” is before a quantitative value, the present teachings also include the specific quantitative value itself, unless specifically stated otherwise. As used herein, the term “about” refers to a ±10% variation from the nominal value.

It should be understood that the order of steps or order for performing certain actions is immaterial so long as the present teachings remain operable. Moreover, two or more steps or actions may be conducted simultaneously.

Where a range or list of values is provided, each intervening value between the upper and lower limits of that range or list of values is individually contemplated and is encompassed within the invention as if each value were specifically enumerated herein. In addition, smaller ranges between and including the upper and lower limits of a given range are contemplated and encompassed within the invention. The listing of exemplary values or ranges is not a disclaimer of other values or ranges between and including the upper and lower limits of a given range.

The aspects, embodiments, features, and examples disclosed herein are to be considered illustrative respects and are not intended to limit the invention, the scope of which is defined only by the claims. Other embodiments, modifications, and usages will be apparent to those skilled in the art without departing from the spirit and scope of the claimed invention.

What is claimed is:

1. A method of locating a radon region indicative of a thermal updraft comprising the steps of:
flying an aircraft in a flight path;
making ionization measurements at a plurality of locations along the aircraft flight path using an ionization measuring device to measure the rate of ionization and the change in the rate of ionization;
determining, in response to the change in ionization rate measurements, areas of increased ionization rate; and
denoting areas of increased ionization rate as areas of thermal updraft.

2. The method of claim 1 further comprising the steps of:
measuring at least one of alpha, beta and gamma radiation intensity level at each location along the aircraft flight path; and
if ionization rate at a respective location is above a predetermined value and if the alpha, beta and gamma radiation intensity levels are above predetermined levels, determining that the location is within a thermal updraft and if ionization rate at the respective location is above a predetermined value and if alpha and beta radiation levels are below a predetermined value determining that the location is outside of a thermal updraft.

3. The method of claim 1 wherein the ionization measurement is a conductivity measurement.

4. The method of claim 1 wherein the ionization measuring device is selected from the group of measuring devices consisting of a Geiger counter, an ion chamber and a scintillation counter.

5. The method of claim 1 further comprising the step of mapping contours of substantially equal ionization rate.

6. The method of claim 5 further comprising the step plotting the contours on a geographic map.

7. The method of claim 1 wherein the areas of increased ionization are denoted in a time graph.

8. The method of claim 1 wherein the areas of increased ionization are denoted by an increase in repetition rate of audible sounds.

9. The method of claim 1 wherein increased ionization is defined as above background ionization.

10. A method of locating a thermal updraft comprising the steps of:
flying an aircraft in a flight path;
detecting radon concentrations at a plurality of locations along the aircraft flight path using an ionization measuring device to measure changes in ionization;
determining, in response to the changes in ionization measurements, areas of increased radon concentration; and
denoting areas of increased radon concentration as areas of thermal updraft.

11. The method of claim 10 further comprising the steps of:
measuring at least one of alpha, beta and gamma radiation at each location along the aircraft flight path; and
if the changes in ionization are above a predetermined level and if alpha and beta radiation levels are above a predetermined value, determining that the location is within a thermal updraft, and if the changes in ionization are above a predetermined level and if alpha and beta radiation levels are below a predetermined value, determining that the location is outside of a thermal updraft.

12. A device of locating a thermal updraft comprising:
a conductivity sensor;
a electrometer in electrical communication with the conductivity sensor; and
a display for showing values of conductivity as a function of time and location.

13. The device of claim 12 wherein the conductivity sensor comprises:
a cylindrical first electrode;
a second electrode positioned within the first electrode; and
a preamplifier in electrical communication with the second electrode.

14. The device of 12 wherein the electrometer comprises:
an isolation amplifier having an output terminal;
an operational amplifier having a first input terminal in electrical communication with the output terminal of the isolation amplifier; an operational amplifier output terminal in electrical communication with the first input terminal of the operational amplifier; and
an electrometer output terminal in electrical communication with the operational amplifier output terminal.

15. The device of claim 12 wherein the conductivity sensor comprises:
a cylindrical first grounded shield;
a cylindrical first electrode within the first grounded shield;
a second electrode positioned within the first electrode; and
a preamplifier in electrical communication with the second electrode.

16. The device of 15 wherein the electrometer comprises:
an operational amplifier having a first input terminal in electrical communication with the output terminal preamplifier; an operational amplifier output terminal in electrical communication with the first input terminal of the operational amplifier; and
an electrometer output terminal in electrical communication with the operational amplifier output terminal.
